(19) United States
(12) Patent Application Publication
(10) Pub. No.: US 2026/0123551 A1
(43) Pub. Date: Apr. 30, 2026

(54) MICROELECTRONIC DEVICE PACKAGE WITH SHAPED END TERMINALS AND METHODS

(71) Applicant: Texas Instruments Incorporated, Dallas, TX (US)

(72) Inventors: Yuqi Zhang, Sichuan (CN); Longti Li, Sichuan (CN); Silijia Xie, Sichuan (CN); Zi Qi Wang, Chengdu (CN)

(21) Appl. No.: 18/931,822

(22) Filed: Oct. 30, 2024

(51) Int. Cl. H01L 23/498; H01L 23/00; H01L 23/14; H01L 23/31; H01L 25/065

(52) U.S. Cl. CPC H10W 90/701; H10W 70/6875; H10W 74/114; H10W 90/00; H10W 72/859; H10W 90/726; H10W 90/756

(57) ABSTRACT

A described example apparatus includes: at least one semiconductor die mounted on a die pad of a package substrate having a first thickness, the package substrate having a device side layer of a second thickness less than the first thickness and having a board side layer of a third thickness less than the first thickness; electrical connections between bond pads and leads formed in the device side layer, the leads connected to corresponding terminals formed in the board side layer; and mold compound covering the device side layer, the electrical connections, and the at least one semiconductor die, the terminals having a board side surface exposed from the mold compound and having a tail portion having a first width, a central portion extending towards the die pad having a second width greater than the first width, and a tapered portion that connects the central portion to the tail portion.

### TECHNICAL FIELD

This disclosure relates generally to microelectronic device packages, and more particularly to a method for fabrication of a no-lead microelectronic device package with a molded package body.

### BACKGROUND

Semiconductor dies are produced for use in electronic circuits using semiconductor wafer manufacturing facilities (sometimes referred to as “wafer fabs”) to form semiconductor dies on a device side surface of a semiconductor wafer. Example semiconductor wafer materials include silicon, germanium, gallium arsenide, gallium nitride, sapphire, silicon carbide and indium phosphide, with silicon being the most used semiconductor wafer material. Example wafer fabrication processes for making semiconductor dies include ion implantation, thermal anneals, thermal oxidation, chemical vapor deposition, dielectric deposition, conductor deposition, sputtering, damascene deposition, chemical mechanical polishing, and passivation layer deposition.

Once the semiconductor dies are complete, the individual devices are removed from the semiconductor wafer by a process referred to as “singulation.” In semiconductor die singulation, the semiconductor wafer is separated into individual semiconductor dies by “wafer dicing.” In one approach, a mechanical saw is used. A rotating saw blade moves along scribe lanes formed between the semiconductor dies and cuts through the semiconductor wafer in multiple passes. During wafer dicing the semiconductor wafer is supported by a removable film or tape, a backside or dicing tape, which supports the dies as the scribe lanes are cut through. Alternative dicing processes include laser dicing and plasma dicing. The semiconductor dies can be square or rectangular in shape. Tens, hundreds or even thousands of semiconductor dies can be formed on a single semiconductor wafer. The scribe lanes are defined areas on the semiconductor wafer between the dies that are parallel to one another in two directions, so that each semiconductor die has four vertical sides after the wafer dicing, the vertical sides extend from a device side surface to a backside surface, so that an individual semiconductor die has six sides, and is a cube.

After the semiconductor wafer is diced into individual semiconductor dies, the individual semiconductor dies can be mounted to a package substrate and a microelectronic device package is formed. In an example process, the individual semiconductor dies are mounted to a die pad, with bond pads on the semiconductor dies facing away from the die pad. A die attach film or die attach epoxy can be used to attach the semiconductor die to the die pad. Electrical connections can be formed between the semiconductor die and leads of the package substrate, for example wire bonds can be formed to couple bond pads on the semiconductor die to the leads of the package substrate. After the electrical connections are formed, a package body can be formed using a mold compound. For example, a transfer molding process can be used to cover the semiconductor die, the electrical connections, and portions of the package substrate with the mold compound, while portions of leads are left exposed from the mold compound to form terminals for the microelectronic device package.

Quad flat no-lead (“QFN”) microelectronic device packages are increasingly used. QFN packages have terminals on a board side surface that are coextensive with a molded package body, and thus when mounted to a board or module, take less board area (when compared to leaded packages where leads extend from the package body). The QFN terminals are exposed for surface mounting on the board side surface of the microelectronic device package.

Defects can arise during the sawing operations used in singulating QFN packages after the molding process forms the package bodies. Metal burrs that result from cutting through the metal leadframe material in saw streets left between the molded devices can sometimes extend between the QFN terminals, forming shorts or current leakage paths.

Improvements are needed for producing reliable and robust microelectronic device packages without manufacturing defects and at reasonable cost.

### SUMMARY

In a described example arrangement, an apparatus includes: at least one semiconductor die mounted on a die pad of a package substrate having a first thickness, the package substrate having a device side layer of second thickness less than the first thickness and having a board side layer of a third thickness less than the first thickness; electrical connections between bond pads on the at least one semiconductor die and leads formed in the device side layer of the package substrate, the leads connected to corresponding terminals formed in the board side layer and having a board side surface; mold compound covering the device side layer, the electrical connections, and the at least one semiconductor die, while the board side surface of the terminals is exposed from the mold compound, the mold compound forming the body of a microelectronic device package for the at least one semiconductor die, the microelectronic device package having a board side surface, an opposing top side surface, four sides between the board side surface and the top side surface, the microelectronic device package having a periphery along the four sides which are normal in direction to the board side surface; wherein the terminals have a tail portion having a first width at the periphery of the microelectronic device package, a central portion extending towards the die pad having a second width that is greater than the first width, and a tapered portion that connects the central portion to the tail portion and tapers from the second width to the first width.

In another described example arrangement, a quad flat no lead (QFN) microelectronic device package includes: a semiconductor die mounted on a die pad of a partially etched leadframe, the die pad having a first thickness that is a full thickness of the partially etched leadframe, the partially etched leadframe having a device side layer of second thickness less than the first thickness and having a board side layer of a third thickness less than the first thickness; wire bonds formed between bond pads on the semiconductor die and leads of the package substrate, the leads connected to corresponding terminals of the partially etched leadframe, the terminals formed in the board side layer and having a board side surface; mold compound covering the device side layer, the wire bonds, and the semiconductor die, while the board side surface of the terminals is exposed from the mold compound, the mold compound forming the body of a microelectronic device package for the semiconductor die, the microelectronic device package having a board side surface, an opposing top side surface, four sides between the board side surface and the top side surface, the microelectronic device package having a periphery along the four sides which are normal in direction to the board side surface; wherein the terminals have a tail portion having a first width at the periphery of the microelectronic device package, a central portion extending towards and spaced from the die pad having a second width that is greater than the first width, and a tapered portion that connects the central portion to the tail portion and tapers from the second width to the first width.

In a described example method arrangement, the method includes: forming a partially etched leadframe having a first thickness, a device side layer of second thickness less than the first thickness, and a board side layer of a third thickness less than the first thickness by performing: patterning the device side layer of the partially etched leadframe to form leads for unit microelectronic device packages in the device side layer; and patterning the board side layer of the partially etched leadframe to form terminals for the unit microelectronic device packages in the board side layer, the leads connected to the terminals, and patterning the partially etched leadframe to form die pads for the unit microelectronic device packages, the die pads positioned in a central portion of the unit microelectronic device packages and spaced from the leads; mounting at least one semiconductor die to the die pads using die attach material; forming electrical connections between bond pads on the at least one semiconductor die and corresponding leads of the unit microelectronic device packages; forming mold compound covering the device side layer, the electrical connections, and the at least one semiconductor dies, while a board side surface of the terminals remains exposed from the mold compound; and sawing the partially etched leadframe along saw streets formed between the unit microelectronic device packages; wherein the terminals have a tail portion having a first width at the periphery of the unit microelectronic device package, a central portion extending towards the die pad for the unit microelectronic device package having a second width that is greater than the first width, and a tapered portion that connects the central portion to the tail portion that reduces from the second width to the first width.

### BRIEF DESCRIPTION OF THE DRAWINGS

FIGS. 1A-B illustrate, in projection views, a semiconductor wafer and an individual semiconductor die, respectively, the individual semiconductor die arranged for wire bonding.

FIGS. 2A-2B illustrate, in a projection view from a top side, and a cross-sectional view, respectively, an example arrangement for a microelectronic device package.

FIGS. 3A-3B illustrate, in a plan view from a board side, and in cross-sectional view, respectively, a microelectronic device package of an arrangement.

FIG. 3C illustrates, in a schematic view, details of a leadframe with leads useful in an arrangement. FIG. 3D illustrates, in another schematic view from a board side, details of the leadframe and leads of FIG. 3C. FIGS. 3E-3F illustrate, in a board side view and a device side view of an example leadframe useful with the arrangements, additional details of the leadframe and terminals.

FIGS. 4A-4C illustrate, in a series of cross-sectional views, example processing steps used to form microelectronic device packages of the arrangements.

FIG. 5 illustrates, in a chart, statistical analysis results for microelectronic device packages of the arrangements, illustrating the performance of the process in forming microelectronic device packages that pass parametric thresholds and without the possibility of burr shorts found in packages formed using a prior approach.

FIG. 6 is a flow diagram illustrating selected steps of a method for forming an arrangement.

### DETAILED DESCRIPTION

Corresponding numerals and symbols in the different figures generally refer to corresponding parts, unless otherwise indicated. The figures are not necessarily drawn to scale.

The term “scribe lane” is used herein. A scribe lane is a portion of semiconductor wafer between semiconductor dies. Sometimes in related literature the term “scribe street” is used. Once processing is finished and the semiconductor devices are complete, the semiconductor devices are separated into individual semiconductor dies by severing the semiconductor wafer along the scribe lanes. The separated dies can then be removed and managed individually for further processing including packaging. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “package substrate” is used herein. A package substrate is a substrate that includes conductive leads arranged to be coupled to a semiconductor die in a semiconductor device package, and to support the semiconductor die. Examples of package substrates useful with the arrangements include leadframes, pre-molded leadframes (“PMLF”), molded interconnect substrates (“MIS”), partially etched or half-etched leadframes, and multilayer substrates including additive build-up substrates such as substrates formed with Ajinomoto Build-Up Film (“ABF”) that is commercially available from the Ajinomoto Co. Inc., in Tokyo Japan, and other laminated substrates. In the description, a package substrate is provided with a strip of device units, each device unit is arranged to provide leads and support for a semiconductor die to be packaged as a semiconductor device package. Note that while a device unit can be a portion of a leadframe, the “frame” portion of a leadframe is removed during packaging to free the individual leads from one another, so to avoid any misinterpretation or confusion, the term “device unit” is used herein for a single unit of a package substrate strip, the device unit includes leads and supports the semiconductor die during packaging and in the semiconductor device package. The package substrate strip can be a leadframe strip but can also be a molded interconnect substrate strip, a routable leadframe strip, or other substrate used for packaging semiconductor devices.

The term “microelectronic device package” is used herein. A microelectronic device package is a package that provide protection for one or more devices, the devices can include a semiconductor die, several semiconductor dies, passive components such as diodes, capacitors, resistors, inductors, transformers, coils, and sensors. The semiconductor dies can be mounted to a package substrate and can be mounted spaced from one another or can be stacked vertically. In some examples passive components can be in a semiconductor die or can be in a discrete package, to form a package-in-package device. Semiconductor device packages containing a single semiconductor die are microelectronic device packages.

The term “saw street” is used herein. Saw streets are areas between the semiconductor device packages on a package substrate that provide areas for sawing between the semiconductor device packages.

Elements are described herein as “coupled.” As used herein, the term “coupled” includes elements that are directly connected, and elements that are electrically connected even with intervening elements or wires are also coupled.

The term “semiconductor die” is used herein. A semiconductor die can be a discrete semiconductor device such as a bipolar transistor, a few discrete devices such as a pair of power field effect transistor (FET) switches fabricated together on a single semiconductor die, or an integrated circuit with multiple semiconductor devices in a circuit such as the multiple capacitors in an A/D converter. The semiconductor die can include passive devices such as resistors, inductors, filters, or active devices such as transistors. The semiconductor die can be an integrated circuit with hundreds or thousands of transistors coupled to form a functional circuit, for example a microprocessor or memory semiconductor device. The semiconductor die can be a passive device such as a sensor, example sensors include photocells, transducers, and charge coupled devices (CCDs), or can be a micromechanical device, such as a digital micromirror device (DMD) or a MEMS device.

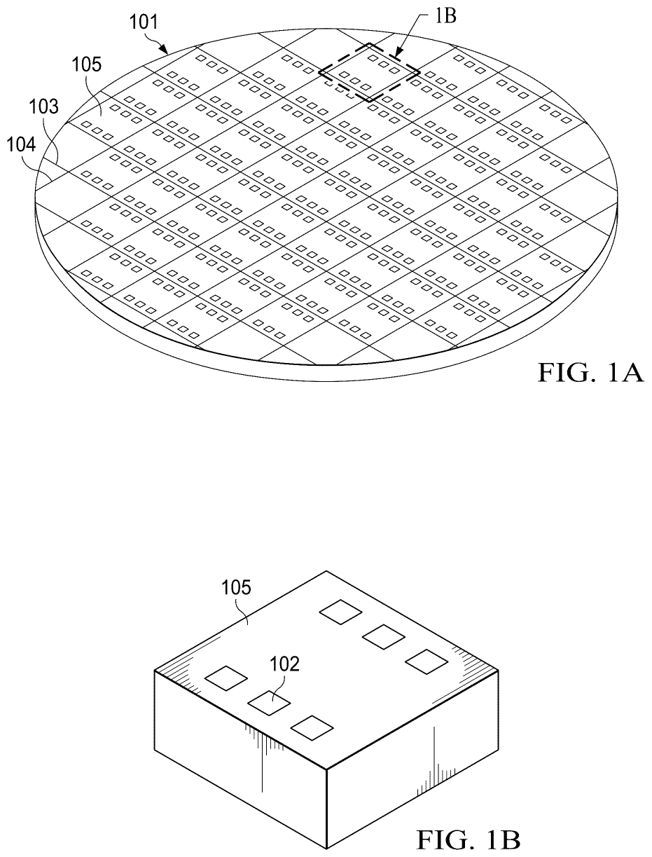

In FIG. 1A, semiconductor wafer 101 is shown with an array of semiconductor dies 105 arranged in rows and columns. The semiconductor dies 105 can be formed using manufacturing processes in a semiconductor manufacturing facility (sometimes referred to as a “wafer fab”), the processes including ion implantation for carrier doping of semiconductor substrates, anneals, oxidation, dielectric and conductor deposition, photolithography, pattern, etch, chemical mechanical polishing (CMP), electroplating, via formation and other processes for making semiconductor devices. Devices (not shown for clarity) are formed on a device side surface of the semiconductor dies during the manufacturing processes. Scribe lanes 103 and 104, which are perpendicular to one another, and which run in parallel groups across the semiconductor wafer 101, separate the rows and columns of the completed semiconductor dies 105, and the scribe lanes 103, 104 provide areas for dicing the wafer to separate the semiconductor dies 105 from one another.

FIG. 1B illustrates in a projection view a single semiconductor die 105 from the semiconductor wafer 101 in FIG. 1A, with bond pads 102, which are conductive pads that are electrically coupled to the devices (the devices are not shown for simplicity of illustration) formed in the semiconductor dies 105. The semiconductor dies 105 can be separated from semiconductor wafer 101 by wafer dicing and are said to be “singulated” from one another, using the scribe lanes 103, 104 (see FIG. 1A).

Dicing is used to singulate the dies 105 from the semiconductor wafer 101. Mechanical saw dicing or laser dicing can be used. Plasma dicing can also be used. The minimum width of the scribe lanes needed for plasma dicing is substantially less than the minimum scribe lane widths required for either laser dicing or mechanical saw dicing, increasing the number of semiconductors dies that can be formed on a single semiconductor wafer, and increasing yields, which can lower unit costs. In some of the example illustrations herein, semiconductor dies are shown with “scalloped” edges, a characteristic of plasma dicing, which uses repeated plasma etch and deposit cycles to form a vertical sidewall in a plasma etch tool. However, other types of wafer dicing can be used with the arrangements, such as laser dicing, and mechanical sawing.

The semiconductor die 105 of FIG. 1B is shown with bond pads 102 ready for wire bonding. The bond pads 102 are prepared to be electrically connected to conductive leads of a package substrate by forming wire bonds. Wire bonds are formed using bond wires that bond to and couple the bond pads 102 to conductive portions of leads of the package substrate, such as a leadframe.

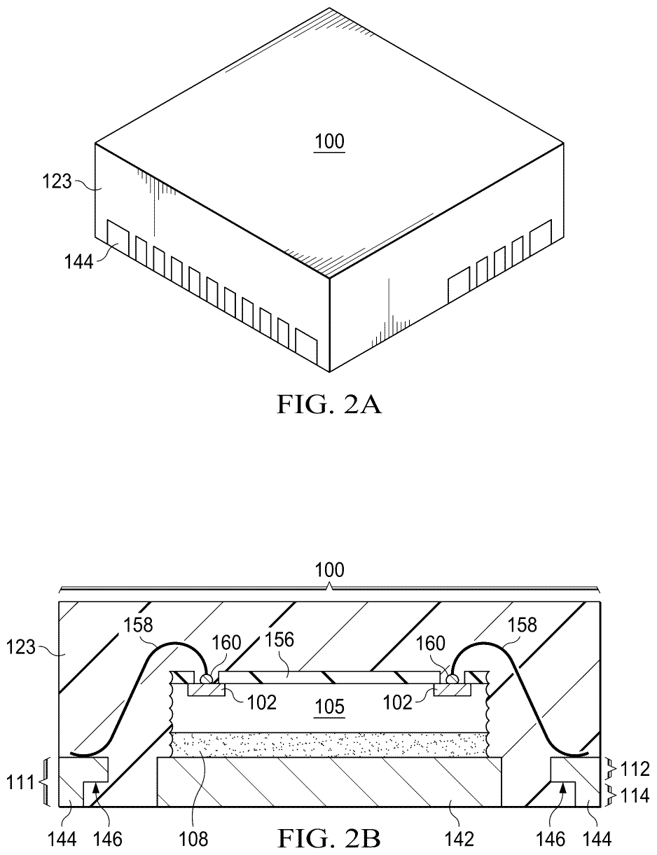

FIG. 2A illustrates, in a projection view, a microelectronic device package of an example arrangement. FIG. 2B illustrates, in a cross-sectional view, the microelectronic device package of FIG. 2A.

In FIG. 2A, microelectronic device package 100 is shown in a projection view from a top side surface. Mold compound 123 forms a package body that covers and protects at least one semiconductor die (not visible in FIG. 2A) and the electrical connections from the semiconductor die to the leads. In the illustrated example, leads of a package substrate are partially covered by mold compound 123, with exposed surfaces forming terminals 144. The terminals 144 have exposed surfaces on at least a board side surface of the microelectronic device package 100. The terminals 144 can be used to mount the device to a board or module using surface mount technology (“SMT”), which uses solder to form physical connections and electrical connections between the microelectronic device package terminals 144, and conductive lands on a board or module.

FIG. 2B illustrates the microelectronic device package 100 of FIG. 2A in a cross-sectional view. In FIG. 2B, at least one semiconductor die 105 is shown mounted to a package substrate 111, which in this example arrangement is a conductive leadframe. In addition to the example arrangement with a single semiconductor die as is shown in FIG. 2B, in alternative arrangements additional passive components or additional semiconductor dies can be mounted in microelectronic device package 100.

The semiconductor die 105 is shown attached to a die pad 142 of package substrate 111 by a die attach material 108. Electrical connections, in this example bond wires 158, are shown attached to bond pads 102 by ball bonds 160. In an alternative arrangement ribbon bonds can be used to form the electrical connections. A protective dielectric layer such as a polyimide (PI) 156 covers the device side surface of the semiconductor die 105, while the bond pads 102 are exposed from the PI layer 156. The bond wires 158 extend to and electrically connect to the leadframe which includes terminals 144. The mold compound 123 covers the electrical connections 158, with the terminals 144 having a board side surface exposed from the mold compound 123. In the arrangements as is described further below, the terminals 144 are formed from a board side layer of the leadframe, and the terminals 144 are shaped to increase the distance between adjacent terminals along a periphery of the microelectronics device package 100, while the board side surface of the terminals have a wider central portion in the interior, to provide a surface area for later surface mounting the microelectronic device package 100 to a board conductive land pattern. Use of the novel shaped end terminals in the arrangements increases the minimum distance between the terminals along the saw cut line, reducing the possibility that a burr or scrap of metal that forms during a sawing operation form shorts between two adjacent terminals, and increasing reliability of the microelectronic device package.

As shown in FIG. 2B, leadframe 111 is formed into two portions, a device side layer lead portion 112, and a board side layer terminal portion 114. The leads and terminals can be formed in a partial etch process for manufacturing the leadframe 111. The partial etch process can begin with a planar sheet of leadframe material, such as copper, or a copper alloy. By etching the sheet of leadframe material in partial etch processes from the device side and from the board side in separate processes, the leadframe can be formed with a device side layer 112, and a board side layer 114, that have different shapes. In addition, in areas where no leadframe material is desired, the partial etch from the two surfaces can be performed to remove all of the material. Further, in areas where a full thickness leadframe portion is needed, such as the die pad 142, no etch is performed. As shown in FIG. 2B, the die pad 142 is spaced from the leads of leadframe 111. In the arrangements, the board side layer 114 is patterned to form terminals that are shaped have a narrow “tail” portion that extends to a dam bar portion of the leadframe that temporarily connects the terminals and leads. The narrow tail is positioned along a cut line in a saw street between the terminals 144 and the dam bar, and when the completed devices are cut apart along the cut lines, the spacing between the adjacent terminals along the saw cut line is increased (with respect to the spacing between the adjacent terminals in a prior approach package without the arrangements). This increased distance between adjacent terminals reduces the likelihood that a saw burr forms a short or current leakage path between the adjacent terminals in a completed microelectronic device package, increasing reliability. Because use of the arrangements does not require modifications to the sawing process or any change to existing tooling, the arrangements can be used and the benefits attained at no or minimal additional cost over prior approaches.

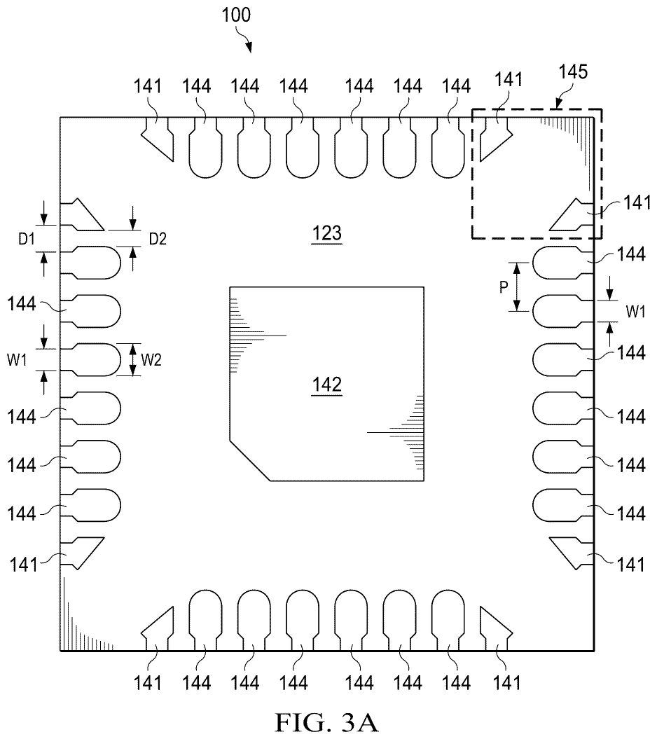

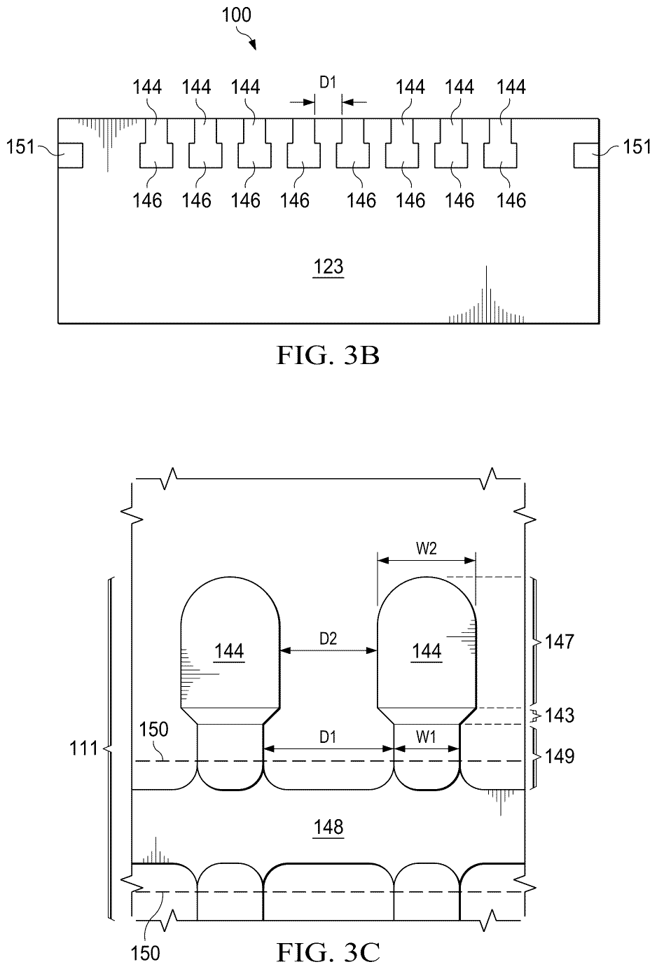

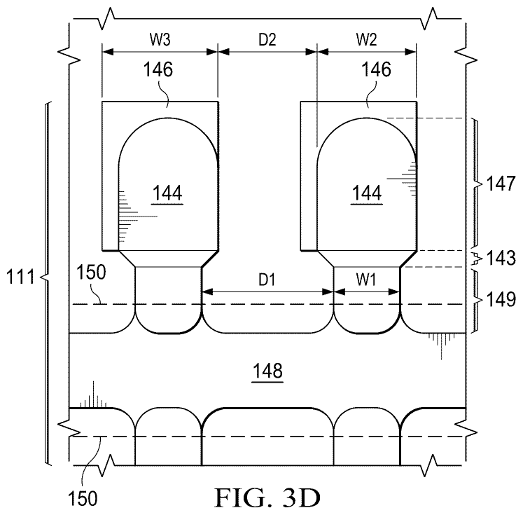

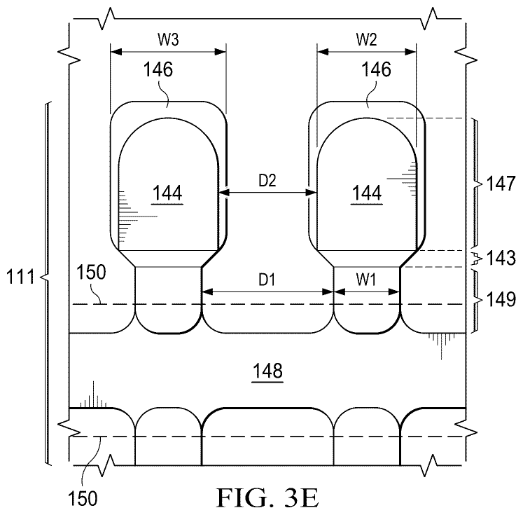

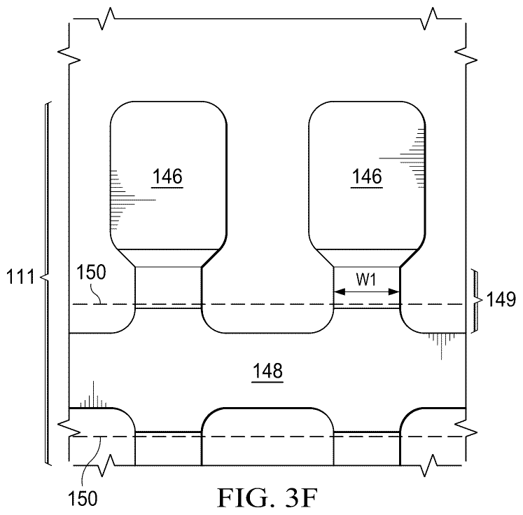

FIG. 3A illustrates the example arrangement microelectronic device package 100 in a plan view from a board side surface. Terminals 144 are shown exposed from mold compound 123 at the board side surface of microelectronic device package 100. The board side surface of the die pad 142 forms a thermal pad for the microelectronic device package 100. By thermally coupling the semiconductor die (see FIG. 2B, 105) to the die pad 142, a thermal path for dissipation of heat from the semiconductor die is provided.

In the arrangements, and as shown in the example illustrated in FIG. 3A, terminals 144 are shaped to have narrow tail sections at the periphery of the microelectronic device package. When the microelectronic device package 100 is formed in a singulation process that removes the molded microelectronic device packages from a leadframe array or grid, a saw blade cuts through the mold compound and the leadframe material between the molded packages and supporting dam bars, including through the narrow tails of the terminals 144. The distance labeled “D1” in FIG. 3A is a first spacing distance between the adjacent terminals 144 at the periphery of the microelectronic device package 100. The first width labeled “W1” shows the width of the narrow tail sections of the terminals 144, while the second width labeled “W2” shows the width of the central portions of the terminals 144 which are interior to the package 100 with respect to the narrow tails, width W2 is greater than width W1, to increase the surface area of the terminals 144 for surface mounting to a board. The second spacing distance “D2” is the spacing between adjacent terminals 144 taken at the central portions. The terminals 144 are spaced apart at a pitch distance “P from center to center. The pitch distance in QFN packages can be part of an industry standard format for a certain package type, standard features are used to assist in designing board patterns for use in mounting the completed devices. In an example package such as the 32 terminal QFN microelectronic device package 100 shown in FIGS. 3A-3B, which can be about 4 millimeters square, one useful pitch distance P is 0.4 millimeters, and the terminals 144 in an example package have widths of about 0.15-0.25 millimeters, with a spacing between terminals of about 0.2 millimeters between the central portions that is increased to about 0.25 millimeters at the periphery. In FIG. 3A, the distance labeled “D2” is the spacing distance between the central portions of the terminals 144, and in the arrangements, the distance D1 between the adjacent terminals at the periphery of the board side surface of the microelectronic device package 100 is greater than the distance D2.

By using a terminal shape with a narrow tail or shaped end portion for terminals 144 in the arrangements, the spacing distance D1 between the adjacent terminals 144 at the periphery of the microelectronic device package 100 is increased (when compared to prior approach packages with QFN terminals having uniform width along the terminal length). By using the shaped end terminals of the arrangements, the increased distance D1 between the adjacent terminals 144 at the periphery of the microelectronics device package advantageously reduces or eliminates the likelihood of an electrical short that could occur due to a metal burr formed at the periphery of the microelectronic device package 100. When burrs are formed in sawing packages formed in a prior approach, sometimes the metal burrs can extend between adjacent terminals. In that case, the metal burr can cause a short defect between the terminals. Because the metal burrs form in the package singulation step, near the end of the packaging process, an otherwise good microelectronic device package scrapped due to a burr defect includes at least one semiconductor device die, the bond wires, and the mold compound, so that scrapping this otherwise good packaged device can increase the costs for completed units substantially.

Also visible in the board side view of FIG. 3A are chamfered terminals 141 in the corner portions 145 of the microelectronic device package 100. By using the chamfered shape for the terminals positioned in these corner portions, these chamfered terminals 141 in the corner portions can be placed in a smaller area, because the chamfered terminals 141 allow for spacing from a tie bar portion (not visible, as the tie bars are covered by the mold compound 123) that extends from the corners of the microelectronic device package 100 to the die pad 142, the tie bars support the die pad 142 during die mounting, wire bonding and molding processes. The tie bar portions remain inside the microelectronic device package 100 after molding and extend as strap shapes from the corners to the die pad, the chamfered shapes of chamfered terminals 141 allow the terminals to be placed closer to the corners of the microelectronic device package without contacting these tie bars, increasing the density of the terminals that can be achieved in a given area of the microelectronic device package 100. As shown in FIG. 3A by the width W1 in the corner portion 145, the chamfered terminals 141 also have the narrow tail portions of the arrangements, advantageously increasing the distance between adjacent terminals at the periphery of the microelectronic device package 100.

FIG. 3B is a cross-sectional of the microelectronic device package 100 of FIG. 3A, oriented with the board side surface facing upwards. The terminals 144 are shown at the board side surface of the mold compound 123 spaced by the spacing distance D1. Portions of the leads 146 are shown beneath terminals 144, these are portions of the partially etched leadframe 111. Portions of tie bars 151 can be seen in the cross section of FIG. 3B in the corner portions of the cross-sectional view.

In the example arrangements, a leadframe can be formed in a partial etch process. In a process for partial etch leadframes useful with the arrangements, a sheet material for the leadframe, such as copper or copper alloy, can be patterned and etched first from one side, and then patterned and etched from the opposite side, each of these etches can be a partial etch. In an example the leadframe can have a total thickness of about 0.2 mm. Partially etched leadframes can have leads and terminals that are connected in a continuous piece, but which are shaped differently on a device side and on a board side, creating leads in a device side layer and terminals in a board side layer with different patterns. Vacant spaces in the leadframe such as spaces between the leads and the die pad, or between individual leads or terminals, can be formed by partially etching the leadframe from both sides, forming openings in the planar sheet of leadframe material at those locations. In FIG. 3B, a portion of the leads can be seen beneath the terminals at the board side surface. A full thickness area, such as the die pads, can be formed simply by not etching that area from either side.

FIG. 3C illustrates, in a schematic view, a portion of leadframe 111, showing further details of terminals 144. In FIG. 3C, two adjacent terminals 144 are shown in a schematic view from a board side showing the board side layer. The spacing distance D2 is shown as the spacing distance between central portions 147 of the terminals 144, and the spacing distance D2 is less than the spacing distance D1 shown between the narrow tail portions 149 of the terminals 144. The distance D1 is shown along the cut lines 150 between the terminals 144 and the cut lines 150 are parallel to a dam bar 148. Dam bar 148 runs between unit leadframe devices and temporarily supports the terminals 144 during processing, and serves to stop mold compound at the boundary of the unit devices. The central portion 147 of terminal 144 is interior with respect to the completed microelectronic device package and extends away from the periphery of a unit microelectronic device package towards the die pad (not shown in FIG. 3C). The second width W2 in the central portion 147 of terminals 144 is greater than the first width W1 of the narrow tail portions 149, which advantageously increases the spacing distance between adjacent ones of terminals 144 along the cut lines 150. Dam bar 148 ties the leads of the leadframe together to provide mechanical support for processing and acts as a dam or stop to mold compound flow from a mold chase during processing. Terminals 144 will be cut away from the dam bar 148 during the singulation process by a saw blade that cuts through the narrow tails of the terminals 144 along the cut lines 150, the saw blade will also cut through any mold compound that is present along the cut lines.

The central portion 147 of the terminals 144 is joined to the narrow tail portion 149 of the terminals 144 by the tapered portion 143 of the terminals 144, which connects the wider central portion 147 to the narrow tail portion 149 with a slanted shape that decreases from the width of the central portion 147 to the width of the tail portion 149. The width W2 of the central portion 147 provides sufficient surface area for soldering the completed package (see 100 in FIG. 3A) to a board or module when a microelectronic device package of the arrangements is surface mounted.

FIG. 3D illustrates, in a more detailed view, the elements of FIG. 3C, again viewed from a board side surface, this illustration now including leads 146. In an example arrangement, the leadframe 111 is formed using a partial etch process to form a board side layer including the terminals 144, and device side layer including leads 146. As shown in FIG. 3D, leads 146 can have a different shape and area than the terminals 144 due to the use of the partial etch process. The leads 146 can be shaped for increased efficiency for wire bonding and can extend farther into the interior of the package to enable better bond wire placement and stitch bond placement. As shown in FIG. 3D, leads 146 can have a third width W3 which, in the illustrated example, is greater than the width W2 of terminals 144. Because the view in FIG. 3D is from the board side, terminals 144 are shown in front of part of leads 146. (In FIG. 3F, described below, a view is shown from the device side and the leads 146 are shown covering the terminals 144, which are obscured in FIG. 3F.)

FIGS. 3C-3D are schematic views, showing ideal shapes of the terminals 144 and the leads 146. In FIG. 3E, a corresponding board side view of a pair of terminals 144 are illustrated; these terminals illustrate examples produced in a prototype process. The leads 146 are also visible in FIG. 3E, in this orientation, the leads 146 are visible behind the terminals 144. In FIG. 3E, the central portions 147 of the terminals 144, which extend into the interior of the device package and end close to the thermal pad in a completed package, are again shown with width W2, and spacing D2. The narrow tail portions 149 are shown with a first width W1 and a first spacing D1, as described above the spacing D1 is greater than the second spacing D2, and in correspondence, the first width W1 of the tail portions 149 is less than the second width W2 of the central portions 147. The tapered portion 143 of terminal 144 is shown continuously decreasing in width and connecting the wider central portion 147 with the narrow tail portion 149. Due to manufacturing tolerances, the tapered portion shown in the illustration of example prototypes is less distinct in shape than in the schematics shown in FIGS. 3C-3D. but it still connects the wider central portion to the narrow tail portion of the terminals 144 at an angle. Cut lines 150 are shown extending parallel to the dam bar 148, at the bottom of the figure a second pair of terminals 144 is shown for another device on the leadframe.

FIG. 3F illustrates, in a plan view of the prototype leadframe taken from a device side surface, the elements of FIG. 3E including leadframe 111. The leads 146 are now shown from the device side, and the terminals 144 are obscured (the terminals 144 are beneath the leads 146 and not visible in this view.) The narrow tail end 149 of the terminals is shown extending to the dam bar 148, with cut lines 150 shown crossing the narrow tail portions. The width W1 of the narrow tail portions is shown. Leads 146 can be shaped to enhance wire bonding or ribbon bonding. The leads 146 will receive a stitch bond in a wire bonding process. The leads 146 extend towards the die pad (not shown) interior to the completed device package.

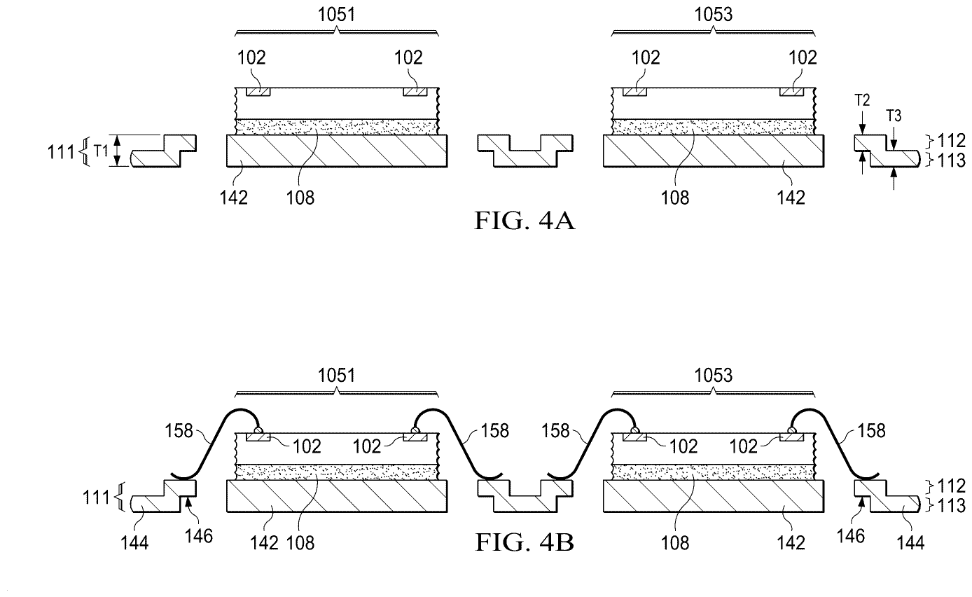

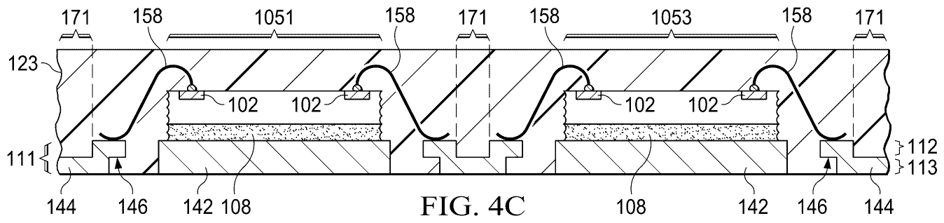

FIGS. 4A-4E illustrate, in a series of cross-sectional views, selected steps of a process to form microelectronic device packages of the arrangements. In FIG. 4A, leadframe 111 is shown with two identical semiconductor dies 1051, 1053 mounted on die pads 142 of two-unit leadframe portions. In a production process, leadframe 111 can include several, tens or hundreds of unit leadframe portions arranged in rows, columns, or a grid of rows and columns, for parallel gang processing to increase the yield in each production run, lowering costs. The semiconductor dies 1051, 1053 correspond to the semiconductor die 105 in FIG. 1B, for example, and are shown after being singulated from a wafer in a plasma dicing process or alternatively, in a saw or laser dicing process. The semiconductor dies 1051, 1053 are mounted to the die pads 142 by a die attach material 108, which can be a die attach epoxy, or a die attach film, and which can be electrically conductive or insulating. In the example arrangements the die attach material 108 is a thermal conductor to assist in heat dissipation to the die pad 142.

FIG. 4B illustrates, in another cross-sectional view, the elements of FIG. 4A after a wire bonding process. In FIG. 4B, leadframe 111, with the device side layer 112 and the board side layer 113 shown, includes the semiconductor dies 1051, 1053 on adjacent unit leadframe portions. The bond pads 102 are electrically coupled to leads 146 by bond wires 158, which as shown in FIG. 4B are “ball and stitch” wire bond connections, with the ball bonds on the bond pads 102, and the stitch bond on the leads 146. The leads 146 are formed in the device side layer 112 of the leadframe 111, and terminals 144 are shown in the board side layer 113, each terminal 144 is connected to a corresponding lead by the leadframe material. The die pads 142 are full thickness portions of the leadframe 111.

FIG. 4C illustrates, in an additional cross-sectional view, the elements of FIG. 4B after a molding step. In FIG. 4C, mold compound 123 covers the semiconductor dies 1051, 1053, the bond wires 158, and portions of the leadframe 111, including the device side layer 112 where leads 146 are formed, and portions of the board side layer 113, where terminals 144 are formed. The board side surfaces of terminals 144, and the die pad 142, are exposed from the mold compound as shown in FIG. 3A and described above and are arranged for use in surface mounting the completed microelectronics device packages to a board.

Mold compound 123 can be formed in a transfer mold using either a block mold or a unit mold in a mold chase. As shown in FIG. 4C, the mold compound 123 forms a block extending over saw streets 171 between the semiconductor dies 1051, 1053. When the devices are singulated to separate them from one another, the sawing process cuts through the mold compound along either side of the saw streets 171, and cuts through the material of leadframe 111 (see for example the dam bar 148 in FIG. 3E) that is present in the saw streets. In an alternative molding approach that is also useful in the arrangements (not shown for simplicity of illustration), a unit mold chase can limit the mold compound so that it covers each semiconductor die (1051, 1053) but does not extend over the saw streets 171, in that approach, the sawing operation cuts through the leadframe 111 but no mold compound is present in the saw streets. Other molding processes can be used to form mold compound 123 such as compression molding. After mold compound 123 is formed, a cure process hardens it to a solid. In a molding process useful with the arrangements, transfer mold tools can use epoxy molding compound provided as a solid puck or as a powdered form to start a molding process. The mold compound is heated in a thermal pot or bowl to a liquid, and then, forced by hydraulic pressure to flow through runners into the mold chases which surround the leadframes, semiconductor dies, and the bond wires. The mold compound fills the molds and is heated to set. Epoxy mold compound is a thermoset material and so forms a solid package body. Curing further hardens the mold compound after molding is complete.

After the molding process of FIG. 4C, a singulation process cuts through the strips or arrays of devices mounted on leadframe 111 along the saw streets 171, and the microelectronic device package 100 of FIG. 2B is produced. Each semiconductor unit 105 is covered by mold compound 123 which forms the body of the microelectronic device package 100. In the arrangements, the board side layer 114 of the leadframe 111 is used to form terminals 144 with a narrow tail portion at the periphery of the package body having a first width, and having a first spacing between adjacent terminals, and a central portion having a second width, and a corresponding second spacing. The first width of the tail portion is less than the second width of the central portion, and the first spacing is greater than the second spacing, the arrangements therefore having a wider spacing between the adjacent terminals (compare to prior approaches with uniform width terminals). The terminals 144 have a tapered portion that extends from the central portion to the narrow tail portion, as shown in FIG. 3A, and further detailed in FIGS. 3C-3E.

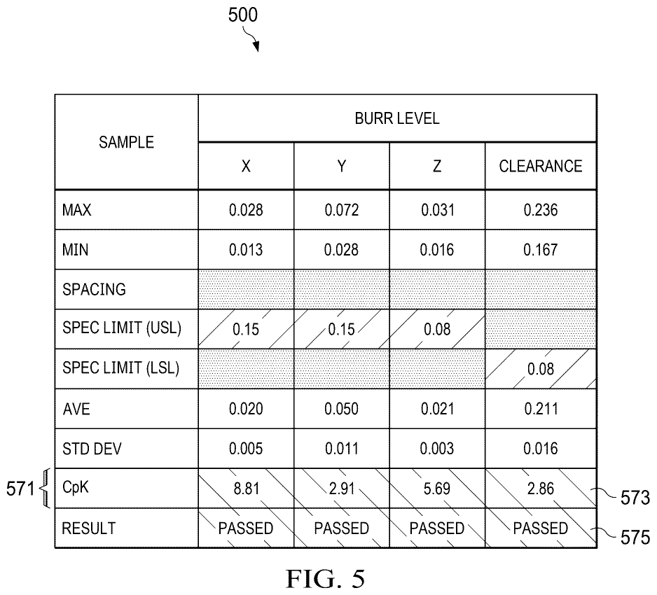

FIG. 5 illustrates, in a chart, results obtained from use of the arrangements to form an example QFN package. In FIG. 5, a process capability index (CpK) (labeled 571 in chart 500) was determined from a statistical analysis of a sample of prototypes produced using the terminals of the arrangements. Burr data was collected, and the clearance characteristics were analyzed. The clearance is an indicator of whether burrs that could form a short between two adjacent terminals were found. In the chart, various burr locations are analyzed, the X direction on the terminals, the Y direction on the terminals, the Z direction on the terminals, and the clearance direction between terminals. In the samples analyzed using the terminals of the arrangements shaped with narrow tails, the process capability index (CpK) for the clearance parameter was determined to be 2.86 (see 573 in chart 500), which exceeds a passing level for the clearance metrics (see the result 575, indicating a pass for the clearance parameter). In a similar analysis of the same package type formed using a prior approach (with uniform width terminal shapes), the process capability index (CpK) for the clearance parameter was determined to be 0.63, which failed to meet the required thresholds for clearance between adjacent terminals. A higher process capability index CpK indicates a process that can more reliably produce outputs within specified limits. The use of the arrangements provides microelectronic device packages that can reliably pass the clearance requirements for burrs between adjacent terminals, in sharp contrast to the microelectronic device packages produced using prior approaches which cannot pass the qualification requirements for burr clearance. Use of the arrangements increased CpK by over four times (from 0.63, a failing result, to 2.86, a passing result).

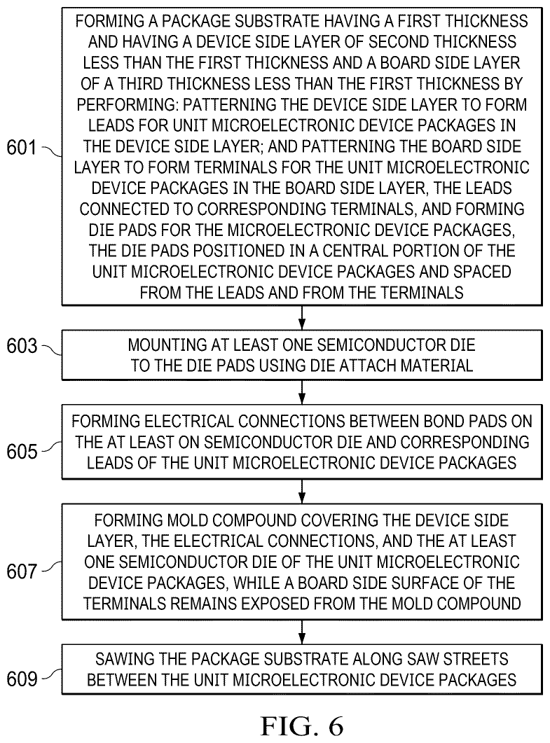

FIG. 6 illustrates, in a flow diagram, a method for forming a microelectronic device package of an arrangement. The method begins at step 601, by forming a package substrate, (for example a leadframe, see 111 in FIG. 4A), the package substrate having a first thickness and having a device side layer of second thickness less than the first thickness and a board side layer of a third thickness less than the first. (See the leadframe 111 in FIG. 4A, with full thickness T1, the device side layer thickness T2, and the board side layer thickness T3). The method forms the package substrate by performing: patterning the device side layer (see layer 112 in FIG. 4A, for example) to form leads (see 146 in FIG. 3D, for example) for unit microelectronic device packages in the device side layer; and patterning the board side layer (see the board side layer 113 in FIG. 4A, for example) to form terminals (see 144 in FIG. 3D, for example) for the unit microelectronic device packages in the board side layer, the leads connected to corresponding terminals, and forming die pads (see 142 in FIG. 4A, for example) for the microelectronic device packages, the die pads positioned in a central portion of the unit microelectronic device packages and spaced from the leads and from the terminals.

At step 603, the method continues by mounting at least one semiconductor die to the die pads using die attach material. (See semiconductor dies 1051, 1053 in FIG. 4A, and die attach material 108 in FIG. 4A).

At step 605, the method continues by forming electrical connections between bond pads on the at least one semiconductor die and corresponding leads of the unit microelectronic device packages. (See, for example, wire bonds 158 in FIG. 4B, leads 146 are connected to the bond pads 102).

At step 607, the method continues by forming mold compound covering the device side layer, the electrical connections, and the at least one semiconductor die of the unit microelectronic device packages, while a board side surface of the terminals remains exposed from the mold compound. (See, for example, mold compound 123 in FIG. 4C, and see terminals 144 in FIG. 3A exposed from the mold compound).

At step 609, the method is completed by sawing the package substrate along saw streets between the unit microelectronic device packages. (See, for example, FIG. 4C illustrating two adjacent semiconductor dies 1051, 1053, and FIG. 2B, illustrating a completed microelectronic device package 100 after sawing is used to separate the units from the package substate). The method forms a microelectronic device package having terminals with a tail portion having a first width at the periphery of the unit microelectronic device package, a central portion extending towards the die pad for the unit microelectronic device package having a second width that is greater than the first width, and a tapered portion that connects the central portion to the tail portion that reduces from the second width to the first width. (See, for example the schematic of the board side layer shown in FIGS. 3C-3D, with terminals 144 shown in detail, and see also the board side view of the microelectronics device package 100 in FIG. 3A, with terminals 144 shown exposed from the mold compound).

Use of the shaped end terminals of the arrangements advantageously increases the spacing between the adjacent terminals along the periphery of microelectronic device packages that are singulated by sawing, increasing the spacing reduces or eliminates shorts formed by metal burrs that occur during sawing of the leadframe material between the molded devices. The arrangements can be formed using a partially etched leadframe with prior existing packaging process tools and materials, and so use of the arrangements can be implemented at low cost.

Modifications and variations are contemplated and can be made in the described arrangements, and other alternative arrangements are possible that are within the scope of the claims.

What is claimed is:

1. An apparatus, comprising:
at least one semiconductor die mounted on a die pad of a package substrate having a first thickness, the package substrate having a device side layer of second thickness less than the first thickness and having an opposing board side layer of a third thickness less than the first thickness;
electrical connections between bond pads on the at least one semiconductor die and leads formed in the device side layer of the package substrate, the leads connected to corresponding terminals formed in the board side layer and having a board side surface; and
mold compound covering the device side layer, the electrical connections, and the at least one semiconductor die, while the board side surface of the terminals is exposed from the mold compound, the mold compound forming the body of a microelectronic device package for the at least one semiconductor die, the microelectronic device package having a board side surface, an opposing top side surface, four sides between the board side surface and the top side surface, the microelectronic device package having a periphery along the four sides which are normal in direction to the board side surface;
wherein the terminals have a tail portion having a first width at the periphery of the microelectronic device package, a central portion extending towards the die pad having a second width that is greater than the first width, and a tapered portion that connects the central portion to the tail portion and tapers from the second width to the first width.

2. The apparatus of claim 1 wherein the microelectronic device package is a quad flat no-lead (QFN) microelectronic device package with terminals on each of the four sides.

3. The apparatus of claim 2, wherein terminals adjacent corners formed between the four sides on the board side surface of the microelectronic device package have chamfered shapes.

4. The apparatus of claim 1, wherein a first spacing between adjacent ones of the terminals at the periphery of the microelectronic device package is greater than a second spacing between the central portions of the adjacent ones of the terminals.

5. The apparatus of claim 4, wherein the microelectronic device package has a width along the sides of the board side surface of about 4 millimeters.

6. The apparatus of claim 5, wherein the first width of the terminals in the central portion is about 0.2 millimeters.

7. The apparatus of claim 5, wherein the second width of the terminals in the tail portion is about 0.15 millimeters.

8. The apparatus of claim 5, wherein the spacing between the adjacent terminals at the periphery of the microelectronic device package is greater than 0.2 millimeters.

9. The apparatus of claim 1, wherein the package substrate is a partially etched metal leadframe.

10. The apparatus of claim 9 wherein the partially etched metal leadframe is of copper or a copper alloy.

11. The apparatus of claim 9 wherein the partially etched metal leadframe has a first thickness of about 0.2 millimeters.

12. A quad flat no lead (QFN) microelectronic device package, comprising:
a semiconductor die mounted on a die pad of a partially etched leadframe, the die pad having a first thickness that is a full thickness of the partially etched leadframe, the partially etched leadframe having a device side layer of second thickness less than the first thickness and having a board side layer of a third thickness less than the first thickness;
wire bonds formed between bond pads on the semiconductor die and leads of the package substrate, the leads connected to corresponding terminals of the partially etched leadframe, the terminals formed in the board side layer and having a board side surface; and
mold compound covering the device side layer, the wire bonds, and the semiconductor die, while the board side surface of the terminals is exposed from the mold compound, the mold compound forming the body of a microelectronic device package for the semiconductor die, the microelectronic device package having a board side surface, an opposing top side surface, four sides between the board side surface and the top side surface, the microelectronic device package having a periphery along the four sides which are normal in direction to the board side surface;
wherein the terminals have a tail portion having a first width at the periphery of the microelectronic device package, a central portion extending towards and spaced from the die pad having a second width that is greater than the first width, and a tapered portion that connects the central portion to the tail portion and tapers from the second width to the first width.

13. The quad flat no lead (QFN) microelectronic device package of claim 12, wherein the die pad of the partially etched leadframe has the first thickness which is about 0.2 millimeters.

14. The quad flat no lead (QFN) microelectronic device package of claim 12, wherein the device side layer and the board side layer have the second thickness and the third thickness of about 0.1 millimeters.

15. The quad flat no lead (QFN) microelectronic device package of claim 12, wherein adjacent terminals have a first spacing that is greater than 0.2 millimeters along the periphery of the microelectronic device package, and a second spacing of about 0.2 millimeters between the central portions of adjacent terminals.

16. The quad flat no lead (QFN) microelectronic device package of claim 12 wherein terminals adjacent to corners formed between the four sides of the microelectronic device package have chamfered shapes at the board side surface.

17. The quad flat no lead (QFN) microelectronic device package of claim 12 wherein the die pad has a board side surface that is exposed from the mold compound to form a thermal pad for the microelectronic device package.

18. The quad flat no lead (QFN) microelectronic device package of claim 17 wherein the semiconductor die is mounted to the die pad using thermally conductive die attach material.

19. A method, comprising:
forming a partially etched leadframe having a first thickness, a device side layer of second thickness less than the first thickness, and a board side layer of a third thickness less than the first thickness by performing:
patterning the device side layer of the partially etched leadframe to form leads for unit microelectronic device packages in the device side layer; and
patterning the board side layer of the partially etched leadframe to form terminals for the unit microelectronic device packages in the board side layer, the leads connected to the terminals, and patterning the partially etched leadframe to form die pads for the unit microelectronic device packages, the die pads positioned in a central portion of the unit microelectronic device packages and spaced from the leads;
mounting at least one semiconductor die to the die pads using die attach material;
forming electrical connections between bond pads on the at least one semiconductor die and corresponding leads of the unit microelectronic device packages;
forming mold compound covering the device side layer, the electrical connections, and the at least one semiconductor dies, while a board side surface of the terminals remains exposed from the mold compound; and
sawing the partially etched leadframe along saw streets formed between the unit microelectronic device packages;
wherein the terminals have a tail portion having a first width at the periphery of the unit microelectronic device package, a central portion extending towards the die pad for the unit microelectronic device package having a second width that is greater than the first width, and a tapered portion that connects the central portion to the tail portion that reduces from the second width to the first width.

20. The method of claim 19, wherein forming the partially etched leadframe further comprises etching a sheet of leadframe material from a first surface to pattern the device side layer and etching the sheet of leadframe material from an opposite second surface to pattern the board side layer.

21. The method of claim 19, wherein forming the electrical connections further comprises performing wire bonding.

22. The method of claim 19, wherein a first spacing between adjacent terminals at the periphery of the unit microelectronic device packages after the sawing is greater than a second spacing between the central portions of the adjacent terminals.

23. The method of claim 19, wherein the unit microelectronic device packages are quad flat no-lead (QFN) packages.
